(19) United States
(12) Patent Application Publication
(10) Pub. No.: US 2026/0106125 A1
(43) Pub. Date: Apr. 16, 2026

(54) PLASMA PROCESSING APPARATUS, CONTROL METHOD, AND CONTROL PROGRAM

(71) Applicant: Tokyo Electron Limited, Tokyo (JP)

(72) Inventors: Joji TAKAYOSHI, Miyagi (JP); Seiji YOKOYAMA, Miyagi (JP)

(73) Assignee: Tokyo Electron Limited, Tokyo (JP)

(21) Appl. No.: 19/420,825

(22) Filed: Dec. 16, 2025

Related U.S. Application Data
(63) Continuation of application No. PCT/JP2024/023401, filed on Jun. 27, 2024.

(30) Foreign Application Priority Data
Jul. 4, 2023 (JP) 2023-110205

(51) Int. Cl. H01J 37/32

(52) U.S. Cl. CPC H01J 37/3299; H01J 37/32642; H01J 37/32697; H01J 2237/3343

(57) ABSTRACT

A plasma processing apparatus for performing plasma processing on a substrate placed on a stage includes: an annular member disposed around the substrate; an adjuster adjusting a sheath thickness above the annular member; a measurer measuring a potential of the annular member; and controller circuitry configured to control values of control parameters in the plasma processing by receiving data indicating a change amount of the potential when an adjustment amount in the adjuster is changed, and data indicating a change amount of the potential when the values of the control parameters are changed for each control parameter, and determining a type of a control parameter to be changed at the same time as the change in the adjustment amount based on the acquired data, and calculates the value of the control parameter to prevent the change amount of the potential accompanying the change in the adjustment amount.

### CROSS-REFERENCE TO RELATED APPLICATIONS

This application is a bypass continuation application of international application No. PCT/JP2024/023401 having an international filing date of Jun. 27, 2024 and designating the United States, the international application being based upon and claiming the benefit of priority from Japanese Patent Application No. 2023-110205, filed on Jul. 4, 2023, the entire contents of each are incorporated herein by reference.

### TECHNICAL FIELD

The present disclosure relates to a plasma processing apparatus, a control method, and a control program.

### BACKGROUND

A plasma processing device is used for plasma-processing a substrate. In a chamber of the plasma processing apparatus, the substrate is disposed in a region surrounded by an annular member called an edge ring or a focus ring.

### CITATION LIST

### Patent Documents

PTL 1: JP2007-258417A

### SUMMARY

The present disclosure provides a plasma processing apparatus, a control method, and a control program which prevent deterioration of process characteristics caused by wear of an annular member disposed in an apparatus.

(1) A plasma processing apparatus according an aspect of the present disclosure is a plasma processing apparatus for performing plasma processing on a substrate placed on a stage, and the plasma processing apparatus includes: an annular member disposed around the substrate; an adjuster adjusting a sheath thickness above the annular member; a measurer measuring a potential of the annular member; and controller circuitry configured to control values of control parameters in the plasma processing by: receiving data indicating a change amount of the potential when an adjustment amount in the adjuster is changed, and data indicating a change amount of the potential when the values of the control parameters are changed for each control parameter, and determining a type of a control parameter to be changed at the same time as the change in the adjustment amount based on the acquired data, and calculates the value of the control parameter to prevent the change amount of the potential accompanying the change in the adjustment amount.

(2) The plasma processing apparatus according to (1), wherein
the control parameters include source power to be supplied to a plasma generation source power and bias power to be supplied to the stage, and
the controller circuitry selects at least one of the source power and the bias power as the control parameter to be changed at the same time as the change in the adjustment amount.

(3) The plasma processing apparatus according to (1), wherein
the controller circuitry determines the type of the control parameter to be changed at the same time as the change in the adjustment amount for each step of a process recipe defining a procedure of the plasma processing, and calculates the value of the determined control parameter.

(4) The plasma processing apparatus according to (1), wherein
the controller circuitry calculates the value of the control parameter to prevent the change amount of the potential accompanying the change in the adjustment amount based on a correlation between the adjustment amount and the change amount of the potential, and a correlation between the value of the control parameter and the change amount of the potential.

(5) The plasma processing apparatus according to (1), wherein
the controller circuitry calculates the value of the control parameter using a learning model that is trained to output the value of the control parameter according to an input of the adjustment amount by using the acquired data as training data.

(6) The plasma processing apparatus according to (1), wherein
the controller circuitry receives the data indicating the change amount of the potential when the adjustment amount in the adjuster is changed, and the data indicating the change amount of the potential when the values of the control parameters are changed for each control parameter, through plasma processing using a dummy substrate.

(7) The plasma processing apparatus according to (1), wherein
the adjuster includes a power source configured to supply power to the annular member.

(8) The plasma processing apparatus according to (1), wherein
the adjuster includes a drive source configured to drive the annular member in an up-down direction.

(9) The plasma processing apparatus according to (1), wherein
the adjuster includes an impedance circuit configured to adjust an impedance of the annular member.

(10) A control method for a plasma processing apparatus for performing plasma processing on a substrate placed on a stage, the plasma processing apparatus including:
an annular member disposed around the substrate,
an adjuster configured to adjust a sheath thickness above the annular member,
a measurer configured to measure a potential of the annular member, and
controller circuitry, the control method comprising:
causing the controller circuitry to: receive, from the plasma processing apparatus, data indicating a change amount of the potential when an adjustment amount in the adjuster is changed, and data indicating a change amount of the potential when the values of the control parameters are changed for each control parameter, and
determine a type of a control parameter to be changed at the same time as the change in the adjustment amount based on the acquired data, and calculate the value of the control parameter to prevent the change amount of the potential accompanying the change in the adjustment amount.

(11) The control method according to (10), wherein
the control parameters include source power to be supplied to a plasma generation source and bias power to be supplied to the stage, and
the method further comprises, by the controller circuitry, selecting at least one of the source power and the bias power as the control parameter to be changed at the same time as the change in the adjustment amount.

(12) The control method according to (10), further comprising:
by the controller circuitry, determining the type of the control parameter to be changed at the same time as the change in the adjustment amount for each step of a process recipe defining a procedure of the plasma processing, and calculating the value of the determined control parameter.

(13) The control method according to (10), further comprising:
by the controller circuitry, calculating the value of the control parameter to prevent the change amount of the potential accompanying the change in the adjustment amount based on a correlation between the adjustment amount and the change amount of the potential, and a correlation between the value of the control parameter and the change amount of the potential.

(14) The control method according to (10), further comprising:
by the controller circuitry, calculating the value of the control parameter using a learning model that is trained to output the value of the control parameter according to an input of the adjustment amount by using the acquired data as training data.

(15) The control method according to (10), further comprising:
by the controller circuitry, receiving the data indicating the change amount of the potential when the adjustment amount in the adjuster is changed, and the data indicating the change amount of the potential when the values of the control parameters are changed for each control parameter, through plasma processing using a dummy substrate.

(16) The control method according to (10), wherein
the adjuster includes a power source, and
the method further comprises, by the adjuster, supplying power to the annular member.

(17) The control method according to (10), wherein
the adjuster includes a drive source, and
the method further comprises, by the adjuster, driving the annular member in an up-down direction.

(18) The control method according to (10), wherein
the adjuster includes an impedance circuit, and
the method further comprises, by the adjuster, adjusting an impedance of the annular member.

(19) A non-transitory computer-readable storage medium storing a computer program that, when executed by a computer, causes the computer to execute a method comprising:
receiving, from a plasma processing apparatus, data indicating a change amount of a potential of an annular member disposed around a substrate in a plasma processing apparatus, when an adjustment amount in an adjuster of the plasma processing apparatus is changed, and data indicating a change amount of the potential when values of control parameters in plasma processing are changed for each control parameter, and
determining a type of a control parameter to be changed at the same time as the change in the adjustment amount based on the acquired data, and calculating the value of the control parameter to prevent the change amount of the potential accompanying the change in the adjustment amount.

(20) The non-transitory computer-readable storage medium according to 19, wherein
the control parameters include source power to be supplied to a plasma generation source power and bias power to be supplied to a stage, and the method further comprises selecting at least one of the source power and the bias power as the control parameter to be changed at the same time as the change in the adjustment amount.

According to the present disclosure, it is possible to prevent the deterioration of the process characteristics caused by the wear of the annular member disposed in the apparatus.

### BRIEF DESCRIPTION OF DRAWINGS

FIG. 1 is a view for explaining an example of a configuration of a capacitively-coupled plasma processing apparatus.

FIG. 2A is a view illustrating a variation of tilting due to wear of an edge ring.

FIG. 2B is a view illustrating a variation of tilting due to wear of the edge ring.

FIG. 3 is a diagram illustrating an action when FRDC_% is changed.

FIG. 4 is a diagram illustrating a method for controlling RF_pw in one or more embodiments.

FIG. 5 is a diagram illustrating a method for calculating an RF_pw change amount.

FIG. 6 is a flowchart illustrating a procedure of processing executed by a controller.

FIG. 7 is a graph illustrating simulation results in a specific step.

FIG. 8 is a graph illustrating simulation results in another step.

### DETAILED DESCRIPTION

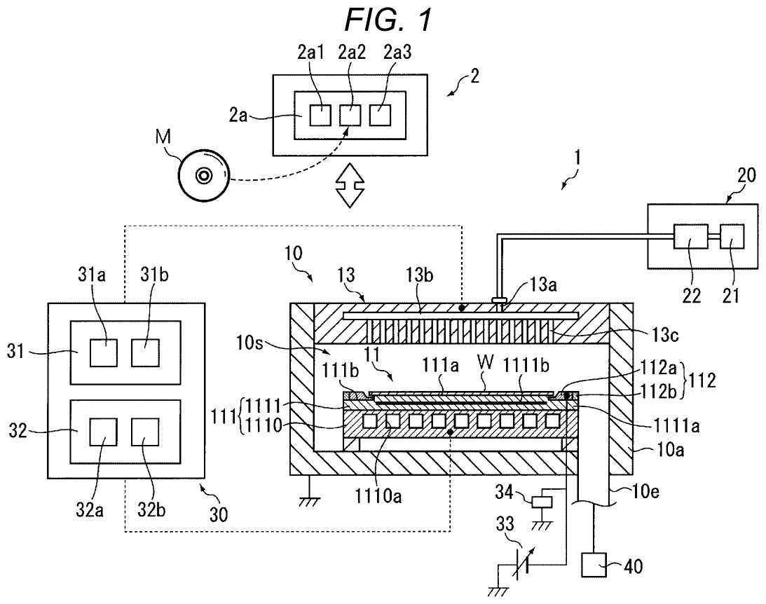

When the plasma processing is executed by the plasma processing apparatus, the annular member is worn and a thickness thereof is reduced. As the thickness of the annular member is reduced, an upper end position of a sheath above the annular member is lowered. When the upper end position of the sheath above the annular member is lowered, ions from a plasma collide with an edge of the substrate at a tilted angle. As a result, a recess formed in the edge of the substrate is tilted. PTL 1 discloses a configuration in which a direct-current voltage is applied to an annular member to prevent tilting of a recess formed in an edge of a substrate. Hereinafter, a configuration example of the plasma processing system will be described. FIG. 1 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one or more embodiments, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one or more embodiments, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one or more embodiments, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one or more embodiments, the one or more annular members include one or more edge rings and at least one cover ring. The edge ring is formed of a conductive material or an insulating material, and the cover ring is formed of an insulating material. The edge ring is also referred to as a focus ring (FR). The ring assembly 112 illustrated in FIG. 1 includes an annular edge ring 112a and an annular cover ring 112b disposed around the edge ring 112a.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one or more embodiments, the flow path 1110a is formed in the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one or more embodiments, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to the plasma processing chamber 10 via at least one impedance matching circuit. The RF power source 31 is configured to supply at least one RF signal (RF power) to at least one lower electrode and/or at least one upper electrode. Accordingly, the plasma is formed from at least one processing gas supplied into the plasma processing space 10s. Accordingly, the RF power source 31 may function as at least a portion of a plasma generator configured to generate a plasma from one or more processing gases in the plasma processing chamber 10. Further, supplying the bias RF signal to at least one lower electrode can generate a bias potential in the substrate W to attract an ionic component in the formed plasma to the substrate W.

In one or more embodiments, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one or more embodiments, the source RF signal has a frequency within a range from 10 MHz to 150 MHz. In one or more embodiments, the first RF generator 31a may be configured to generate a plurality of source RF signals having different frequencies. The generated one or more source RF signals are supplied to the at least one lower electrode and/or the at least one upper electrode. Hereinafter, the source RF power (source power) will also be referred to as HF_pw.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one or more embodiments, the bias RF signal has a frequency lower than the frequency of the source RF signal. In one or more embodiments, the bias RF signal has a frequency within a range from 100 kHz to 60 MHz. In one or more embodiments, the second RF generator 31b may be configured to generate a plurality of bias RF signals having different frequencies. The generated one or more bias RF signals are supplied to the at least one lower electrode. In various embodiments, at least one of the source RF signal and the bias RF signal may be pulsed. Hereinafter, the bias RF power (bias power) will also be referred to as LF_pw. The source RF power and the bias RF power are also referred to as RF_pw when there is no need to distinguish the source RF power and the bias RF power from each other.

Further, the power source 30 may include a DC power source 32 coupled to the plasma processing chamber 10. The DC power source 32 includes a first DC generator 32a and a second DC generator 32b. In one or more embodiments, the first DC generator 32a is connected to at least one lower electrode and configured to be to generate a first DC signal. The generated first bias DC signal is applied to the at least one lower electrode. In one or more embodiments, the second DC generator 32b is configured to be connected to at least one upper electrode to generate a second DC signal. The generated second DC signal is applied to the at least one upper electrode.

In various embodiments, at least one of the first and second DC signals may be pulsed. In this case, a sequence of pulse voltages is applied to at least one lower electrode and/or at least one upper electrode. The pulse voltage may have a pulse waveform of a rectangle, a trapezoid, a triangle, or a combination thereof. In one or more embodiments, a waveform generator for generating a sequence of pulse voltages from the DC signal is connected between the first DC generator 32a and at least one lower electrode. Accordingly, the first DC generator 32a and the waveform generator configure a pulse voltage generator. In a case where the second DC generator 32b and the waveform generator configure the pulse voltage generator, the pulse voltage generator is connected to at least one upper electrode. The pulse voltage may have a positive polarity or a negative polarity. Further, the sequence of the pulse voltages may include one or more positive pulse voltages and one or more negative pulse voltages in one cycle. The first and second DC generators 32a and 32b may be provided in addition to the RF power source 31, and the first DC generator 32a may be provided instead of the second RF generator 31b.

The plasma processing system includes a variable direct-current power source 33 coupled to the edge ring 112a, and an electrometer 34 that measures a potential of the edge ring 112a. In one or more embodiments, the variable direct-current power source 33 is connected to the edge ring 112a and generates a third DC signal. The generated DC signal is applied to the edge ring 112a. Hereinafter, a voltage of the third DC signal applied to the edge ring 112a is also referred to as FRDC, and an adjustment amount of the third DC signal is also referred to as FRDC_%. The electrometer 34 is a contact-type or non-contact-type electrometer and measures the potential of the edge ring 112a. Data of the potential measured by the electrometer 34 is output to the controller 2.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control elements of the plasma processing apparatus 1 to execute the various steps described herein below. In one or more embodiments, part or all of the controller 2 may be in the plasma processing apparatus 1. The controller 2 may include a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, and is read from the storage 2a2 and executed by the processor 2a1. The medium may be various recording media M readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

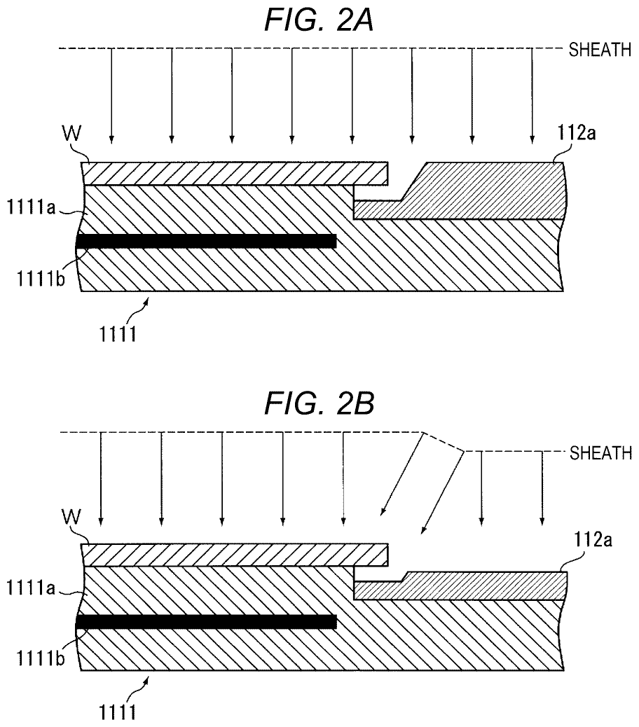

Next, changes in sheath and occurrence of tilting caused by wear of the edge ring 112a will be described. FIGS. 2A and 2B are views illustrating a variation of tilting due to the wear of the edge ring 112a.

FIG. 2A illustrates a state where the edge ring 112a is not worn. The edge ring 112a is disposed on the annular region 111b of the substrate support 11 as a part of the ring assembly 112. A thickness of the edge ring 112a is designed such that a height of an upper surface of the edge ring 112a and a height of an upper surface of a wafer W coincide with each other when the edge ring 112a is disposed on the annular region 111b. When the edge ring 112a is not worn, the sheath on the wafer W generated during the plasma processing and the sheath on the edge ring 112a have the same thickness, and no step occurs.

At this time, an irradiation angle of ions to the wafer W and the edge ring 112a is substantially perpendicular to the surfaces thereof. As a result, a shape (an etching shape) of a recess formed in the wafer W is substantially perpendicular in both a central region and a peripheral region of the wafer W, and tilting in which the shape of the recess is oblique does not occur.

In the plasma processing, the edge ring 112a is exposed to the plasma and is gradually worn. FIG. 2B illustrates a state where the edge ring 112a is worn. When the thickness of the edge ring 112a is thinner due to the wear, the upper surface of the edge ring 112a is lower than the upper surface of the wafer W. As a result, as illustrated in FIG. 2B, a step is generated between the sheath above the edge ring 112a and the sheath above the wafer W.

As a result of the occurrence of the step in the sheath, an irradiation direction of ions is oblique in the peripheral region of the wafer W as indicated by arrows in the drawing, and tilting in which the shape of the recess formed in the wafer W is oblique occurs.

As one of method for eliminating the tilting caused by the wear of the edge ring 112a, a method for changing the FRDC_% according to an RF application time and adjusting the thickness of the sheath formed above the edge ring 112a is known.

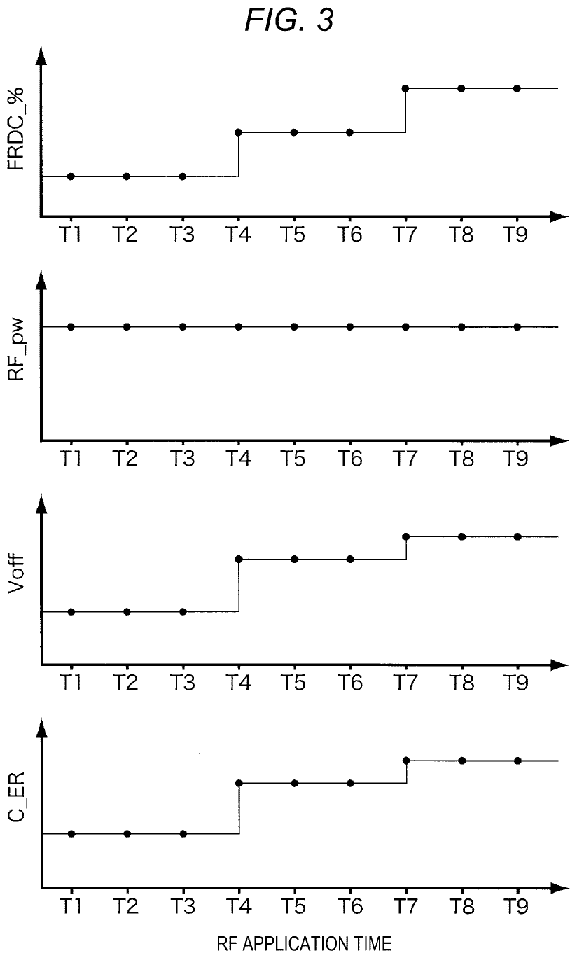

FIG. 3 is a diagram illustrating an action when FRDC_% is changed. A graph illustrated in the uppermost row of FIG. 3 represents a time change in FRDC_%. A horizontal axis of the graph represents the RF application time, and a vertical axis represents FRDC_%. Here, the RF application time represents a time during which RF_pw is supplied from the RF power source 31 to a plasma generation source and the lower electrode. FRDC_% represents a ratio index indicating how much more an FRDC application amount is to be added to a self-bias (Voff). The graph illustrated in the uppermost row of FIG. 3 illustrates an example in which FRDC_% is increased by a required increase amount at timings when the RF application times reach T4 and T7, respectively. By changing the voltage (FRDC) applied from the variable direct-current power source 33 to the edge ring 112a according to FRDC_%, the thickness of the sheath formed above the edge ring 112a can be adjusted.

In the present embodiment, a configuration is described in which the FRDC application amount is adjusted using the ratio index (FRDC_%), but a configuration may be adopted in which the FRDC application amount is adjusted using a difference (FRDC_V) in voltage values instead of the ratio index.

A second graph from the top in FIG. 3 represents a time change in RF_pw. A horizontal axis of the graph represents the RF application time, and a vertical axis represents RF_pw. RF_pw represents the source RF power (or the bias RF power supplied to the lower electrode) supplied to the plasma generation source. The second graph from the top in FIG. 3 illustrates an example in which RF_pw is not changed.

A third graph from the top in FIG. 3 represents a time change in Voff. A horizontal axis of the graph represents the RF application time, and a vertical axis represents Voff. Voff represents the potential of the edge ring 112a and is a value measured by the electrometer 34. The third graph from the top in FIG. 3 illustrates that when FRDC_% is increased without changing the value of RF_pw, the potential of the edge ring 112a increases according to the increase in FRDC_%.

A graph illustrated at the bottom in FIG. 3 represents a time change in C_ER. A horizontal axis of the graph represents the RF application time, and a vertical axis represents C_ER. C_ER represents an etching rate of a substrate central portion. The etching rate is, for example, a value measured by a meter that optically measures a pattern shape in a substrate surface. The graph at the bottom in FIG. 3 illustrates that when FRDC_% is increased without changing the value of RF_pw, the etching rate of the substrate central portion increases according to the increase in FRDC_%.

From experimental results in FIG. 3, it can be understood that the etching rate of the substrate central portion increases when FRDC_% is increased according to the RF application time without changing the value of RF_pw to eliminate the tilting caused by the wear of the edge ring 112a. In addition, from the experimental results in FIG. 3, it can be understood that there is a correlation between the etching rate of the substrate central portion and the potential of the edge ring 112a.

Therefore, the inventors of the present application have focused on the potential of the edge ring 112a that correlates with the etching rate of the substrate central portion, and propose a method for calculating RF_pw such that the potential of the edge ring 112a does not vary when the FRDC_% is changed, and controlling the RF_pw to prevent the increase in the etching rate in the substrate central portion.

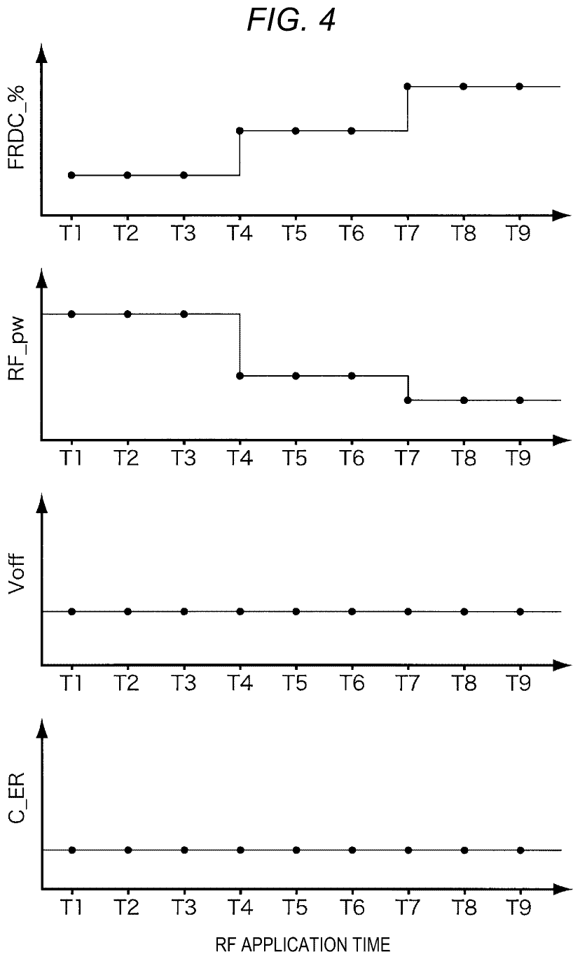

FIG. 4 is a diagram illustrating a method for controlling RF_pw in one or more embodiments. A graph illustrated in the uppermost row of FIG. 4 represents a time change in FRDC_%. A horizontal axis of the graph represents the RF application time, and a vertical axis represents FRDC_%. The graph illustrated in the uppermost row of FIG. 4 illustrates an example in which FRDC_% is increased by a required increase amount at timings when the RF application times reach T4 and T7, respectively.

A second graph from the top in FIG. 4 represents a time change in RF_pw. A horizontal axis of the graph represents the RF application time, and a vertical axis represents RF_pw. The second graph from the top in FIG. 4 illustrates an example in which RF_pw is reduced at the same timings as the timings (T4 and T7) when the FRDC_% is increased.

A third graph from the top in FIG. 4 represents a time change in Voff. A horizontal axis of the graph represents the RF application time, and a vertical axis represents Voff. When the value of RF_pw is calculated and controlled such that Voff does not vary, a time variation of Voff is prevented as illustrated in the third graph from the top in FIG. 4.

The graph illustrated at the bottom in FIG. 4 represents a time change in C_ER. A horizontal axis of the graph represents the RF application time, and a vertical axis represents C_ER. When the value of RF_pw is calculated and controlled such that Voff does not vary, a time variation is also prevented for the etching rate (C_ER) of the substrate central portion correlated with Voff, as illustrated in graph illustrated at the bottom in FIG. 4.

Hereinafter, a method for calculating an RF_pw change amount will be described.

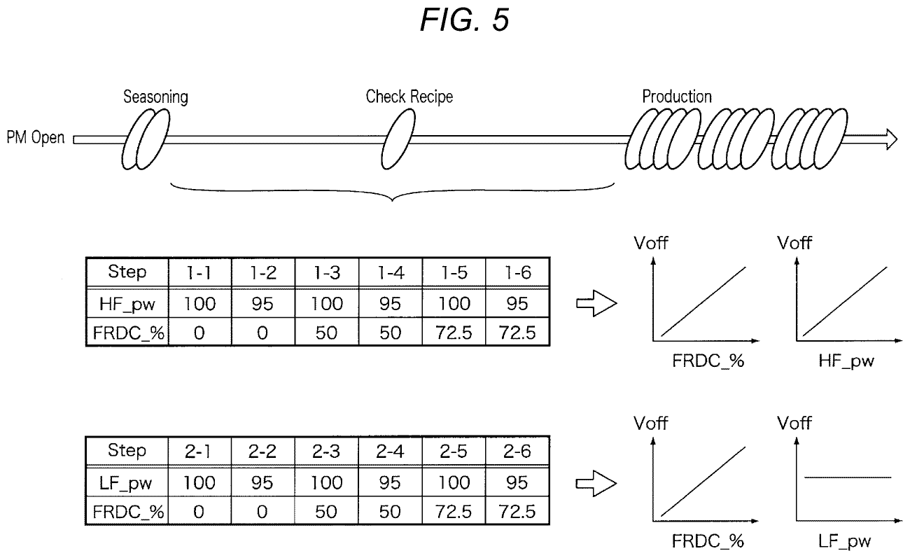

FIG. 5 is a diagram illustrating the method for calculating the RF_pw change amount. After completing part maintenance such as replacement of consumables, dry cleaning in the processing chamber, seasoning for bringing the inside of the processing chamber close to a state at the time of stable mass production, and the like, the controller 2 of the plasma processing system executes a check recipe using a dummy substrate. The check recipe includes a step of varying RF_pw in stages and measuring Voff (the potential of the edge ring 112a) at that time. The controller 2 calculates the RF_pw change amount using data obtained when the check recipe is executed. The data used for the calculation is preferably collected for each type of step such as cutting an organic film or cutting a silicon film.

The controller 2 increases FRDC_% by the required increase amount every set time to counteract the tilting caused by the wear of the edge ring 112a. For example, the increase amount of FRDC_% can be determined according to the RF application time, such as increasing FRDC_% by 10% every 50 hours until the RF application time elapses by 200 hours, and increasing FRDC_ % by 15% every 50 hours after 200 hours elapse. Timings for increasing FRDC_% and the increase amount when correcting FRDC_% are not limited to the above-described examples, and can be designed in advance according to a degree of tilting formed on the substrate W.

During the execution of the check recipe, the controller 2 increases FRDC_% according to the RF application time, and collects Voff data when RF_pw is varied in stages. The example of FIG. 5 illustrates an example in which Voff data obtained when FRDC_% is increased according to the RF application time and HF_pw is changed in stages, and Voff data obtained when LF_pw is changed in stages, are collected for a specific step (for example, a step of cutting an organic film).

The controller 2 calculates a change amount of RF_pw that prevents the variation in Voff, based on the collected data. Specifically, the controller 2 can determine a control parameter (HF_pw or LF_pw in this example) to be changed at the same time as the change in FRDC_%, and a value thereof, based on the correlation between FRDC_%, RF_pw, and Voff.

For example, as illustrated in the graph of FIG. 5, it is understood that Voff increases according to an increase in FRDC_% and Voff increases according to an increase in HF_pw, from the data obtained when the check recipe is executed. In this case, when HF_pw is reduced when FRDC_% is increased, an increase in Voff can be prevented. Meanwhile, it is understood that Voff increases according to the increase in FRDC_%, and Voff does not change according to the increase in LF_pw. In this case, even when LF_pw is increased or reduced when FRDC_% is increased, the increase in Voff cannot be prevented. Therefore, in the example illustrated in FIG. 5, the controller 2 selects “HF_pw” as the control parameter to be changed at the same time as the change in FRDC_%.

FIG. 5 illustrates an example in which HF_pw is selected as the control parameter to be changed at the same time as the change in FRDC_%. However, depending on the type of step, LF_pw may be selected, and both HF_pw and LF_pw may be selected.

The controller 2 calculates a value of the control parameter (HF_pw in the example of FIG. 5) to be changed at the same time as the change in FRDC_%, regarding the selected control parameter. Specifically, the controller 2 calculates an adjustment amount a of FRDC_% according to the RF application time, a ratio (a gradient) b at which Voff increases with respect to FRDC_%, and a ratio (a gradient) c at which Voff increases with respect to HF_pw, from the data obtained when the check recipe is executed, and derives a calculation formula for calculating the value of the control parameter (HF_pw in the example of FIG. 5) after the change using the adjustment amount a of FRDC_% as an input. The above calculation formula can be derived by using a regression method. The controller 2 calculates the value of the control parameter by using the derived calculation formula. The controller 2 may calculate the value of the control parameter (a value after the change), or may calculate a change amount of the control parameter.

Instead of the configuration in which the value of the control parameter is calculated using the calculation formula, a configuration may be adopted in which the value of the control parameter is derived using a learning model such as machine learning. The learning model uses the data obtained when the check recipe is executed as training data, and is trained to output a value of the control parameter when the adjustment amount a of FRDC_% is received.

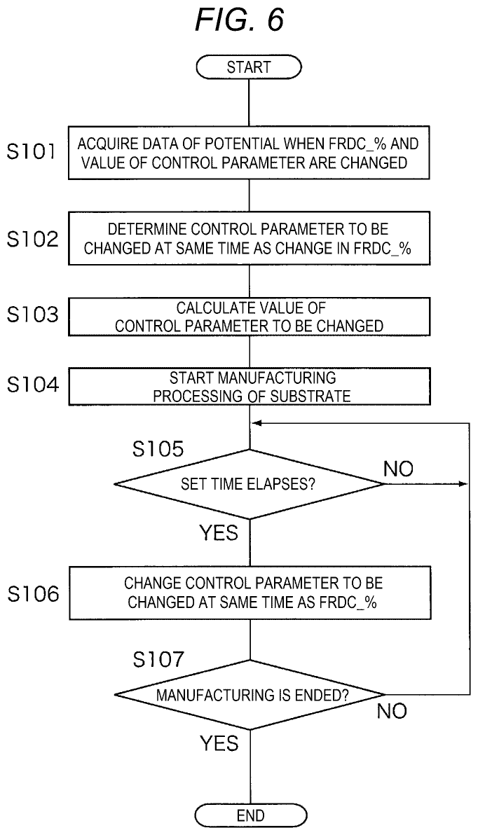

FIG. 6 is a flowchart illustrating a procedure of processing executed by the controller 2. After completing the processing such as the part maintenance, the dry cleaning, and the seasoning, the controller 2 executes the following processing according to the check recipe using the dummy substrate.

During the execution of the check recipe using the dummy substrate, the controller 2 changes FRDC_% and the value of the control parameter in stages, and acquires the data of the potential of the edge ring 112a measured by the electrometer 34 (step S101). The acquired data of the potential is stored in the storage 2a2 together with FRDC_% and the value of the control parameter. FRDC_% and the value of the control parameter which are stored in storage 2a2 may be set values or actually measured values.

Based on the acquired data, the controller 2 determines the control parameter to be changed at the same time as the change in FRDC_% (step S102). In one or more embodiments, the control parameter to be changed at the same time as the change in FRDC_% is determined using Voff (the potential of the edge ring 112a) as a standard, which is strongly correlated with C_ER (an amount of etching in the substrate central portion). Specifically, the controller 2 examines the correlation between FRDC_% and Voff and the correlation between the control parameter and Voff, and selects a control parameter that can cancel the variation of Voff when FEDC_V is changed.

Based on the acquired data, the controller 2 calculates the value of the control parameter to be changed at the same time as the change in FRDC_% (step S103). The controller 2 uses the adjustment amount a of FRDC_%, the ratio (the gradient) b at which Voff increases with respect to FRDC_%, and the ratio (the gradient) c at which Voff increases with respect to HF_pw to derive the calculation formula for calculating the value of the control parameter, using the adjustment amount a of FRDC_% as an input. The controller 2 calculates the value of the control parameter by using the derived calculation formula.

The controller 2 stores the type of the selected control parameter and the calculated value of the control parameter in the storage 2a2. Alternatively, the controller 2 may embed the value of the control parameter in a manufacturing recipe for manufacturing a desired substrate. The controller 2 may notify an external device through the communication interface 2a3 of the type of the selected control parameter and the calculated value of the control parameter. A notification destination may be another plasma processing apparatus that performs the same steps as those in the plasma processing apparatus 1, or may be a management server that manages these plasma processing apparatuses.

After executing the check recipe using the dummy substrate, the controller 2 executes the following processing according to the manufacturing recipe for manufacturing a desired substrate.

The controller 2 starts manufacturing processing of the substrate according to the manufacturing recipe (step S104). The controller 2 counts the RF application time using a built-in clock and determines whether a set time elapses (step S105). If the set time does not elapse (NO in S105), the controller 2 is on standby until the set time elapses.

If it is determined that the set time elapses (YES in step S105), the controller 2 changes the FRDC_%, and changes the value of the control parameter to be changed at the same time as the FRDC_% according to a calculation result in step S103 (step S106). Since the value of the control parameter is calculated to cancel the variation of Voff in step S103, the variation of Voff can be prevented by changing the value of the control parameter according to the calculation result. As a result, it is possible to prevent the variation of C_ER which is strongly correlated with Voff.

The controller 2 refers to the manufacturing recipe to determine whether to end the manufacturing processing (step S107). If it is determined that the manufacturing processing is not ended (NO in step S107), the controller 2 returns the processing to step S105. If it is determined that the manufacturing processing is ended (YES in S107), the controller 2 ends the processing according to the flowchart.

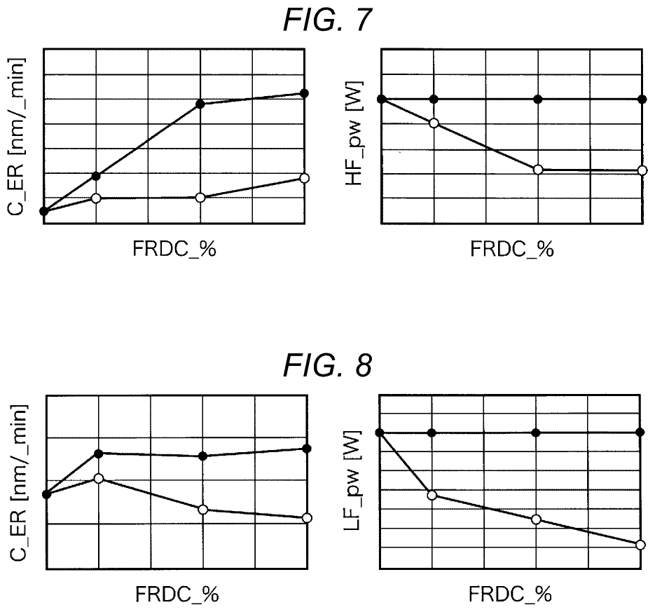

FIG. 7 is a graph illustrating simulation results at a specific step. FIG. 7 illustrates simulation results in a specific step (for example, a step of cutting an organic film). Of two graphs illustrated in FIG. 7, a left graph represents a change in C_ER with respect to FRDC_%, and a right graph represents a change in HF-pw with respect to FRDC_%. In each graph, black circles represent simulation results when HF_pw is not changed, and white circles represent simulation results when HF_pw is changed.

In the above step, when HF_pw is not changed with respect to the adjustment of FRDC_ %, C_ER is significantly varied as indicated by black circles in the left graph. For example, 10.3% increase in C_ER is observed for a 25% adjustment amount (FRDC_%). In contrast, when HF_pw is selected as the control parameter and HF_pw is reduced as illustrated by the white circles in the right graph, the variation of C_ER is prevented, and C_ER rises by 2.9% with respect to the adjustment amount (FRDC_%) of 25%.

FIG. 8 is a graph illustrating simulation results in another step. FIG. 8 illustrates simulation results in another step (a step of cutting a silicon film). Of two graphs illustrated in FIG. 8, a left graph represents a change in C_ER with respect to FRDC_%, and a right graph represents a change in LF-pw with respect to FRDC_%. In each graph, black circles represent simulation results when LF_pw is not changed, and white circles represent simulation results when LF_pw is changed.

In the above step, when LF_pw is not changed with respect to the adjustment of FRDC_ %, C_ER is significantly varied as indicated by black circles in the left graph. For example, 1.9% increase in C_ER is observed for a 25% adjustment amount (FRDC_%). In contrast, when LF_pw is selected as the control parameter and LF_pw is reduced as illustrated by the white circles in the right graph, the variation of C_ER is prevented, and C_ER fell by 1.0% with respect to the adjustment amount (FRDC_%) of 25%.

As described above, in one or more embodiments, when FRDC_% is increased according to the RF application time, the control parameter to be changed for each step in each process recipe is selected based on the potential of the edge ring 112a which is strongly correlated with C_ER, and the variation of C_ER (the etching rate in the substrate central portion) can be prevented by changing the value of the selected control parameter at the same time as the adjustment of FRDC_%.

In one or more embodiments, the variation of C_ER (the etching rate in the substrate central portion) is prevented by adjusting RF power. However, the variation of C_ER may be prevented by adjusting parameters relating to a pulsed signal such as a duty ratio or a cycle, instead of the RF power.

In one or more embodiments, either the HF_pw or the LF_pw is selected as the control parameter to be adjusted. However, since a plasma processing system that performs plasma processing using one type of HF and two types of LF is also present, at least one control parameter to be adjusted may be selected from three types of control parameters.

In one or more embodiments, the variable direct-current power source 33 is disclosed as a unit for adjusting the sheath thickness above the edge ring 112a. Alternatively, the sheath thickness may be adjusted by supplying a pulsed direct-current voltage to the edge ring 112a. In this case, the control parameter may be adjusted, by the controller 2, at the same time as the change in the pulsed direct-current voltage to prevent the variation of C_ER (the etching rate in the substrate central portion).

An adjustment circuit that adjusts an impedance of the edge ring 112a may be provided, and the sheath thickness may be adjusted by adjusting the impedance of the edge ring 112a. In this case, the control parameter may be adjusted at the same time as the change in the impedance to prevent the variation of C_ER (the etching rate in the substrate central portion).

The sheath thickness may be adjusted by moving the position of the edge ring 112a in an up-down direction. In this case, the control parameter may be adjusted at the same time as vertical driving of the edge ring 112a to prevent the variation of C_ER (the etching rate in the substrate central portion).

In one or more embodiments, the controller 2 executes correction processing. Alternatively, an external server such as a cloud server capable of communicating with the controller 2 may execute the correction processing. Further, a program (i.e., A non-transitory computer-readable storage medium having computer-executable instructions stored thereon) installed in the controller 2 may be provided as a program product.

The embodiments disclosed herein are exemplary in all respects and are required to be considered to be not restrictive embodiments. The scope of the present invention is indicated by the scope of the aspects, not the meaning described above, and is intended to include meanings equivalent to the scope of the aspects and all changes within the scope. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

Although an example is described in the above embodiments in which the present disclosure is applied to the capacitively-coupled plasma processing device 1, the present disclosure is not limited to the capacitively-coupled plasma processing device 1, and can be applied to a plasma processing device of any type such as an inductively coupled plasma (ICP), a radial line slot antenna (RLSA), an electron cyclotron resonance plasma (ECR), and a helicon wave plasma (HWP).

Although the wafer W is described as an example of the substrate to be processed in the embodiments described above, the substrate to be processed is not limited to the wafer W, and may be various types of substrates, printed substrates, or the like used for a flat panel display (FPD).

1. A plasma processing apparatus for performing plasma processing on a substrate placed on a stage, the plasma processing apparatus comprising:
an annular member disposed around the substrate,
an adjuster adjusting a sheath thickness above the annular member,
a measurer measuring a potential of the annular member, and
controller circuitry configured to control values of control parameters in the plasma processing by: receiving data indicating a change amount of the potential when an adjustment amount in the adjuster is changed, and data indicating a change amount of the potential when the values of the control parameters are changed for each control parameter, and
determining a type of a control parameter to be changed at the same time as the change in the adjustment amount based on the acquired data, and calculates the value of the control parameter to prevent the change amount of the potential accompanying the change in the adjustment amount.

2. The plasma processing apparatus according to claim 1, wherein
the control parameters include source power to be supplied to a plasma generation source power and bias power to be supplied to the stage, and
the controller circuitry selects at least one of the source power and the bias power as the control parameter to be changed at the same time as the change in the adjustment amount.

3. The plasma processing apparatus according to claim 1, wherein
the controller circuitry determines the type of the control parameter to be changed at the same time as the change in the adjustment amount for each step of a process recipe defining a procedure of the plasma processing, and calculates the value of the determined control parameter.

4. The plasma processing apparatus according to claim 1, wherein
the controller circuitry calculates the value of the control parameter to prevent the change amount of the potential accompanying the change in the adjustment amount based on a correlation between the adjustment amount and the change amount of the potential, and a correlation between the value of the control parameter and the change amount of the potential.

5. The plasma processing apparatus according to claim 1, wherein
the controller circuitry calculates the value of the control parameter using a learning model that is trained to output the value of the control parameter according to an input of the adjustment amount by using the acquired data as training data.

6. The plasma processing apparatus according to claim 1, wherein
the controller circuitry receives the data indicating the change amount of the potential when the adjustment amount in the adjuster is changed, and the data indicating the change amount of the potential when the values of the control parameters are changed for each control parameter, through plasma processing using a dummy substrate.

7. The plasma processing apparatus according to claim 1, wherein the adjuster includes a power source configured to supply power to the annular member.

8. The plasma processing apparatus according to claim 1, wherein
the adjuster includes a drive source configured to drive the annular member in an up-down direction.

9. The plasma processing apparatus according to claim 1, wherein
the adjuster includes an impedance circuit configured to adjust an impedance of the annular member.

10. A control method for a plasma processing apparatus for performing plasma processing on a substrate placed on a stage, the plasma processing apparatus including:
an annular member disposed around the substrate,
an adjuster configured to adjust a sheath thickness above the annular member,
a measurer configured to measure a potential of the annular member, and
controller circuitry, the control method comprising:
causing the controller circuitry to: receive, from the plasma processing apparatus, data indicating a change amount of the potential when an adjustment amount in the adjuster is changed, and data indicating a change amount of the potential when the values of the control parameters are changed for each control parameter, and
determine a type of a control parameter to be changed at the same time as the change in the adjustment amount based on the acquired data, and calculate the value of the control parameter to prevent the change amount of the potential accompanying the change in the adjustment amount.

11. The control method according to claim 10, wherein
the control parameters include source power to be supplied to a plasma generation source and bias power to be supplied to the stage, and
the method further comprises, by the controller circuitry, selecting at least one of the source power and the bias power as the control parameter to be changed at the same time as the change in the adjustment amount.

12. The control method according to claim 10, further comprising:
by the controller circuitry, determining the type of the control parameter to be changed at the same time as the change in the adjustment amount for each step of a process recipe defining a procedure of the plasma processing, and calculating the value of the determined control parameter.

13. The control method according to claim 10, further comprising:
by the controller circuitry, calculating the value of the control parameter to prevent the change amount of the potential accompanying the change in the adjustment amount based on a correlation between the adjustment amount and the change amount of the potential, and a correlation between the value of the control parameter and the change amount of the potential.

14. The control method according to claim 10, further comprising:
by the controller circuitry, calculating the value of the control parameter using a learning model that is trained to output the value of the control parameter according to an input of the adjustment amount by using the acquired data as training data.

15. The control method according to claim 10, further comprising:
by the controller circuitry, receiving the data indicating the change amount of the potential when the adjustment amount in the adjuster is changed, and the data indicating the change amount of the potential when the values of the control parameters are changed for each control parameter, through plasma processing using a dummy substrate.

16. The control method according to claim 10, wherein
the adjuster includes a power source, and
the method further comprises, by the adjuster, supplying power to the annular member.

17. The control method according to claim 10, wherein
the adjuster includes a drive source, and
the method further comprises, by the adjuster, driving the annular member in an up-down direction.

18. The control method according to claim 10, wherein
the adjuster includes an impedance circuit, and
the method further comprises, by the adjuster, adjusting an impedance of the annular member.

19. A non-transitory computer-readable storage medium storing a computer program that, when executed by a computer, causes the computer to execute a method comprising: receiving, from a plasma processing apparatus, data indicating a change amount of a potential of an annular member disposed around a substrate in a plasma processing apparatus, when an adjustment amount in an adjuster of the plasma processing apparatus is changed, and data indicating a change amount of the potential when values of control parameters in plasma processing are changed for each control parameter, and
determining a type of a control parameter to be changed at the same time as the change in the adjustment amount based on the acquired data, and calculating the value of the control parameter to prevent the change amount of the potential accompanying the change in the adjustment amount.

20. The non-transitory computer-readable storage medium according to claim 19, wherein
the control parameters include source power to be supplied to a plasma generation source power and bias power to be supplied to a stage, and
the method further comprises selecting at least one of the source power and the bias power as the control parameter to be changed at the same time as the change in the adjustment amount.
